(19) United States
(12) Patent Application Publication
(10) Pub. No.: US 2014/0342533 A1
(43) Pub. Date: Nov. 20, 2014

(54) METHOD OF STRAIN AND DEFECT CONTROL IN THIN SEMICONDUCTOR FILMS

(71) Applicant: Applied Materials, Inc., Santa Clara, CA (US)

(72) Inventor: Yi-Chiau HUANG, Fremont, CA (US)

(21) Appl. No.: 14/278,454

(22) Filed: May 15, 2014

Related U.S. Application Data
(60) Provisional application No. 61/823,713, filed on May 15, 2013.

(51) Int. Cl. H01L 21/02

(52) U.S. Cl. CPC H01L 21/02532; H01L 21/02609
USPC 438/478

(57) ABSTRACT

A method of managing strain and preventing defect formation in semiconductor materials is described. In structures featuring two or more semiconductor materials with different lattice constants, buffer layers may be used to form deposition surfaces that result in defect-free semiconductor devices. The buffer layers typically have compositions, and lattice constants, intermediate between the two semiconductor materials. The buffer layers may have stepped or graded composition, and multiple buffer layers may be used.

### CROSS-REFERENCE TO RELATED APPLICATIONS

This application claims benefit of U.S. provisional patent application Ser. No. 61/823,713, filed May 15, 2013, which is herein incorporated by reference.

### FIELD

Technology described herein relates to manufacture of semiconductor devices. More specifically, methods are described of forming germanium features on a silicon substrate.

### BACKGROUND

Germanium was one of the first materials used for semiconductor applications such as CMOS transistors. Due to vast abundance of silicon compared to germanium, however, silicon has been the overwhelming semiconductor material of choice for CMOS manufacture. As device geometries decline according to Moore's Law, the size of transistor components poses challenges to engineers working to make devices that are smaller, faster, use less power, and generate less heat. For example, as the size of a transistor declines, the channel region of the transistor becomes smaller, and the electronic properties of the channel become less viable, with more resistivity and higher threshold voltages. Interest in germanium has been reignited recently due to its narrow bandgap, which is helpful in engineering smaller devices.

Typically a germanium containing feature is formed on a silicon substrate. Silicon and germanium have substantial mismatch between the lattice constants of the two materials. The lattice constant of germanium is about 5.66 Å, while that of silicon is about 5.43 Å. When germanium is formed on silicon, germanium atoms try to adopt a spacing similar to the spacing of the silicon atoms, resulting in compressive stress among the germanium atoms. As the germanium becomes thicker, germanium atoms will dislocate to their preferred spacing, resulting in strain relaxation and creating defects in the lattice. These defects lead to less desirable electrical properties as conduction pathways through the crystal lattice are disrupted.

A popular use of germanium containing materials is in FINFET devices. A trench between two oxide isolators is filled with germanium, and the isolators are removed to form the gate of the FINFET. The lattice mismatch between silicon and germanium, however, poses challenges in such devices because the defects caused by the latice mismatch disrupt the electrical characteristics of the device.

Thus, there is a continuing need for methods and apparatus for forming defect-free semiconductor heteroepitaxial structures.

### SUMMARY

A method of managing strain and preventing defect formation in semiconductor materials is described. In structures featuring two or more semiconductor materials with different lattice constants, buffer layers may be used to form deposition surfaces that result in defect-free semiconductor devices. The buffer layers typically have compositions, and lattice constants, intermediate between the two semiconductor materials. The buffer layers may have stepped or graded composition, and multiple buffer layers may be used.

A buffer layer is useful in preventing defect formation in the silicon-germanium system. A faceted silicon-germanium buffer layer may be formed on a silicon substrate between oxide isolators, and a defect-free germanium layer may be formed on the silicon-germanium buffer layer.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram summarizing a method according to one embodiment.

FIG. 2 is a side view of a semiconductor structure according to one embodiment.

FIG. 3 is a side view of a semiconductor structure according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

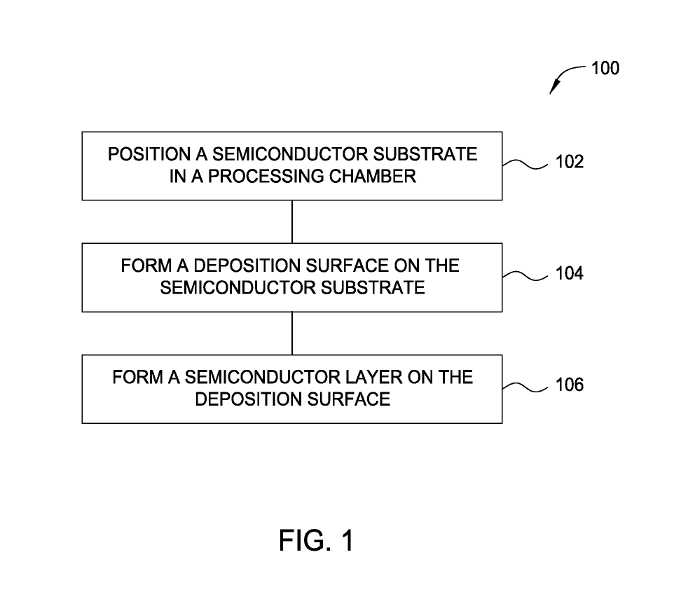

Strain may be controlled in forming lattice-mismatched layers for semiconductor devices by using a buffer layer, and by using strain in the buffer layer to adjust the lattice constant of the buffer layer in desired ways. FIG. 1 is a flow diagram summarizing a method 100 according to one embodiment. A semiconductor substrate is positioned in a processing chamber at 102. The semiconductor substrate has one or more portions on which a semiconductor feature is to be formed. The semiconductor substrate may be any semiconductive material on which a lattice mismatched layer is to be formed. A silicon substrate, or a substrate having one or more silicon regions, on which a germanium containing FINFET structure is to be formed is one example. The substrate may have any known semiconductive materials, such as silicon, germanium, carbon, group III/V semiconductor materials, group II/VI semiconductor materials, and combinations or mixtures thereof. For example, the substrate may have silicon areas and germanium areas. The substrate may also have areas that are a mixture of silicon and germanium.

The semiconductor substrate may also have dielectric areas formed on a surface thereof. For example, a substrate on which a FINFET structure is to be formed typically has dielectric spacers formed adjacent to semiconductive regions to control formation of the FINFET structure. The dielectric areas may be oxides such as silicon oxide, nitrides, carbides, oxynitrides, oxycarbides, or combinations thereof. Metal oxides, metal nitrides, group IV oxides, group IV nitrides, group IV carbides, group IV oxynitrides, group IV, oxycarbides, low K dielectrics, high K dielectrics, glasses, ceramics, and combinations or mixtures thereof may be present in the substrate to be treated according to the method 100 of FIG. 1. The dielectric areas, which may be isolators, may define the portions of the substrate surface on which semiconductor features are formed, for example between the isolators.

A deposition surface is formed on the substrate at 104. The deposition surface may be formed by depositing a first semiconductor material on the one or more portions of the substrate surface in a way that presents a facet with a lattice spacing along the surface that is longer than the shortest unit cell dimension of the deposited material. Such deposition may be performed between the dielectric areas. The first semiconductor feature typically comprises the first semiconductor material and a second semiconductor material. Typically, if the second semiconductor material is deposited on the first semiconductor material, a lattice mismatch occurs when the first semiconductor material has a first lattice constant, the second semiconductor material has a second lattice constant, and the first and second lattice constants are substantially different, for example by more than about 3%. In the case of silicon and germanium, silicon has a lattice constant of about 5.43 Å while germanium has a lattice constant of about 5.66 Å, a lattice mismatch of 4.2%. If germanium is to be deposited directly on silicon, the lattice mismatch results in strain relaxation and defect formation within a few monolayers of the interface.

The lattice mismatch may be reduced somewhat by using a buffer material to form the deposition surface. The buffer material may be a blend of the first and second materials. In the silicon-germanium example, a mixture, blend, or alloy, of silicon and germanium may be used. The mixture has a lattice constant that is different from that of the pure first material by an amount roughly proportional to the amount of the second material in the mixture. The lattice constant of the buffer material may thus be extended to an intermediate value between the lattice constant of the first material and that of the second material. The buffer layer acts to absorb a portion of the strain resulting from the lattice mismatch, so the buffer layer may be a strain absorber layer.

Multiple buffer layers may be used. The buffer layers may have the same composition or different composition. Any number of buffer layers may be used. Each buffer layer may have a different composition from one or more adjacent buffer layers. Each buffer layer may have a different composition from a buffer layer above and a buffer layer below. In the case of a second material being deposited on a first material, with a buffer layer between, the buffer layer may be a multi-layer where each sub-layer of the multi-layer has a different concentration of the first material and the second material. The concentration of the second material in the first material may migrate monotonically from sub-layer to sub-layer to transition to a deposition surface that yields a low defect rate during deposition of the second material. The first layer deposited on the first material typically has a low concentration of the second material, while the layer providing the deposition surface may have a high concentration of the second material. Typically each layer deposited will have a lattice mismatch of no more than about 3% with the subjacent layer to avoid strain relaxation and defect generation. In the case of a silicon germanium buffer layer deposited on a silicon substrate, a single buffer layer of 30% silicon and 70% germanium enables growth of a defect-free germanium layer to a thickness of approximately 30 nm or thicker.

The deposition surface may be further prepared or matched to the second material by using selective strain to further extend the lattice constant of the deposition surface. If the second material has a lattice constant larger than the first material on which it is to be deposited, a tensile strain may be added to the deposition surface of the buffer material described above by manipulating boundary conditions for formation of the buffer material. Otherwise, a compressive strain may be added to the deposition surface of the buffer material.

One way of selecting strain in the deposition surface is to use differential affinity for the substrate material and a boundary material, such as an isolator. By selecting a buffer material and a boundary material such that the buffer material has higher affinity for the substrate material than for the boundary material, the buffer material will normally yield a deposition surface with a tensile strain. Silicon germanium mixtures can be deposited on a silicon substrate between silicon oxide isolators to provide a buffer layer having a deposition surface with tensile strain. The deposition surface for such a material is usually in the (111) direction, which is to say in a lattice bias direction.

A silicon germanium buffer layer having a suitable deposition surface may be deposited in a trench on a silicon substrate between two silicon oxide isolators by disposing the substrate in a vapor deposition chamber and flowing a gas mixture into the chamber. The gas mixture contains one or more silicon containing compounds and one or more germanium containing compounds. The silicon containing compounds and germanium containing compounds may be organosilicon and organogermanium compounds, hydrides, halides, or a mixture thereof. Inert gases such as noble gases, nitrogen, carbon dioxide, or mixtures thereof may be used as carrier gases. The silicon and germanium compounds may be flowed to the chamber through different pathways to avoid unwanted side reactions. The substrate is typically maintained at a temperature of about 300° C. to about 600° C., for example 450° C., and the chamber pressure is maintained between about 1 mTorr and about 200 Torr, for example about 10 Torr. The substrate may be rotated during the deposition, and the gas mixture may be directed to flow across the substrate surface substantially parallel to the surface.

When a silicon germanium layer is grown on a silicon substrate between two silicon oxide isolators with substantially vertical walls, the silicon germanium layer grows in a faceted shape, typically along the (111) direction. The (111) surface of the silicon germanium layer has a tensile stress that increases the lattice constant of the deposition surface, further reducing the mismatch with germanium.

The composition and thickness of a buffer layer as described above affects strain relaxation and defect formation in the layer formed over the buffer layer. As noted above, increasing compositional similarity between the buffer layer and the underlying substrate decreases lattice mismatch at the interface between the buffer layer and the substrate, while increasing compositional similarity between the buffer layer and layers formed over the buffer layer decreases lattice mismatch and defect formation in the above layer. In some cases, a buffer layer with a gradient composition may be used. In an embodiment featuring a silicon substrate in which a germanium fin is to be formed, a buffer layer may be initiated from a precursor mixture that is mostly silicon precursors, for example 95% silicon precursors and 5% germanium precursors by volume. As deposition of the buffer layer proceeds, the flow rate of silicon precursors may be ramped downward while the flow rate of germanium precursors is ramped upward to a final precursor mixture composition that is 95% germanium precursors and 5% silicon precursors. Alternately, precursor flow rates may be adjusted in steps, for example in ten steps, during formation of the buffer layer. Such a buffer layer effectively has a lattice constant that varies across the thickness of the buffer layer from a silicon-like value to a germanium-like value.

A semiconductor layer is formed on the deposition surface at 106. The semiconductor layer is typically a material that has a significant lattice constant mismatch relative to the underlying substrate material, as with silicon and germanium described above.

Layers with silicon and germanium are typically deposited by providing a precursor mixture that has silicon precursor materials and germanium precursor materials. The silicon and germanium precursors are typically hydrides, such as germanes (GeₓH₂ₓ₊₂) and silanes (SiₓH₂ₓ₊₂). The silicon and germanium precursors may be delivered using a carrier gas, which may be a non-reactive gas such as nitrogen gas, hydrogen gas, or a noble gas such as helium or argon, or a combination thereof. The ratio of precursor volumetric flow rate to carrier gas flow rate may be used to control gas flow velocity through the chamber. The ratio may be any proportion from about 1% to about 99%, depending on the flow velocity desired. In some embodiments, a relatively high velocity may improve uniformity of the formed layer. In a 300 mm single-wafer embodiment, the flow rate of germanium precursor may be between about 0.01 sLm and about 2.0 sLm. For a chamber having a volume of about 50 L, at the above flow rates for germanium precursor, carrier gas flow rate between about 5 sLm and about 40 sLm provides a uniform layer thickness. The Epi™ chamber available from Applied Materials, Inc., of Santa Clara, Calif., or other CVD and epitaxy chambers from other manufacturers, may be used to form the layers described herein.

A deposition control agent may be provided to the processing chamber to control deposition on the surface of the substrate. The deposition control agent allows selective deposition on the semiconductive areas of the substrate at satisfactory deposition rates, while controlling deposition on dielectric areas, in some cases effectively preventing deposition on the dielectric areas. It is believed that the deposition control agent inhibits deposition on the dielectric regions of the substrate. Thus, the deposition control agent is a selectivity control agent because selectivity may be controlled by adjusting the amount of the selectivity control agent relative to the reactive species in the reaction mixture.

The deposition control agent is typically a halogen containing species, such as a group IV halide, for example dichlorosilane. Other common examples are hydride or halogen gases such as hydrogen chloride (HCl) or chlorine gas (Cl₂). Useful deposition control agents are typically fluorine containing agents, chlorine containing agents, or bromine containing agents, or mixtures thereof. Some may be fluorides, chlorides, and/or bromides, and some may be compounds containing more than one halogen species. The group IV components are usually silicon, germanium, carbon, or combinations thereof. Molecules including silicon and germanium, silicon and carbon, carbon and germanium, or silicon carbon and germanium may be used as deposition control agents. Organic chlorosilanes or organic chlorogermanes may be used, for example, along with their bromo-homologues. Exemplary deposition control agents include, but are not limited to, silicon tetrachloride, silicon tetrabromide, germanium tetrachloride, germanium tetrabromide, carbon tetrachloride, carbon tetrabromide, trichlorosilane, trichlorogermane, dichlorosilane, dichlorogermane, monochlorosilane, monochlorogermane, alkyl halosilanes having the formula RₓSiX₄₋ₓ, wherein x is 0 to 4, R is any alkyl or alkylene group, and X is Cl or Br, and alkyl halogermanes having the formula RₓGeX₄₋ₓ, wherein x is 0 to 4, R is any alkyl or alkylene group, and X is Cl or Br. Combination agents such as agents having the formula X¹ₓR₃₋ₓSiGeR′_{y}X²_{3-y} may also be used.

Usable alkyl halosilanes include chloromethylsilane, dichloromethylsilane, trichloromethylsilane, dichlorodimethylsilane, chlorodimethylsilane, chlorotrimethylsilane, bromomethylsilane, dibromomethylsilane, tribromomethylsilane, dibromodimethylsilane, bromodimethylsilane, bromotrimethylsilane, chloroethylsilane, dichloroethylsilane, trichloroethylsilane, dichlorodiethylsilane, chlorodiethylsilane, chlorotriethylsilane, bromoethylsilane, dibromoethylsilane, tribromoethylsilane, dibromodiethylsilane, bromodiethylsilane, bromotriethylsilane, chloromethylethylsilane, chlorodimethylethylsilane, chloromethyldiethylsilane, bromomethylethylsilane, bromodimethylethylsilane, bromomethyldiethylsilane, chloromethylgermane, dichloromethylgermane, trichloromethylgermane, dichlorodimethylgermane, chlorodimethylgermane, chlorotrimethylgermane, bromomethylgermane, dibromomethylgermane, tribromomethylgermane, dibromodimethylgermane, bromodimethylgermane, bromotrimethylgermane, chloroethylgermane, dichloroethylgermane, trichloroethylgermane, dichlorodiethylgermane, chlorodiethylgermane, chlorotriethylgermane, bromoethylgermane, dibromoethylgermane, tribromoethylgermane, dibromodiethylgermane, bromodiethylgermane, bromotriethylgermane, chloromethylethylgermane, chlorodimethylethylgermane, chloromethyldiethylgermane, bromomethylethylgermane, bromodimethylethylgermane, bromomethyldiethylsilane, fluoromethylsilane, difluoromethylsilane, trifluoromethylsilane, difluorodimethylsilane, fluorodimethylsilane, fluorotrimethylsilane, fluoromethylsilane, difluoromethylsilane, trifluoromethylsilane, difluorodimethylsilane, fluorodimethylsilane, fluorotrimethylsilane, fluoromethylethylsilane, fluorodimethylethylsilane, fluoromethyldiethylsilane, fluoromethylgermane, difluoromethylgermane, trifluoromethylgermane, difluorodimethylgermane, fluorodimethylgermane, fluorotrimethylgermane, fluoroethylgermane, difluoroethylgermane, trifluoroethylgermane, difluorodiethylgermane, fluorodiethylgermane, fluorotriethylgermane, fluoromethylethylgermane, fluorodimethylethylgermane, and fluoromethyldiethylgermane. It should be noted that compounds described above having more than one halogen, such as the di-halo, tri-halo, and tetra-halo compounds, may have mixed halogens. So, for example, a compound such as chlorobromosilane or fluorochlorosilane, or similar permutations of other compounds listed above, may be used. As those of skill in the art will appreciate from the foregoing non-exhaustive list, other variants of alkyl halosilanes and alkyl halogermanes are contemplated for use in practicing the methods described herein. Organic chlorides such as chloromethane, dichloromethane, and the like permuted similar to the list above, are also contemplated for use.

The deposition control agent may be provided at a flow rate between about 0 sccm and about 1000 sccm, such as between about 100 sccm and about 500 sccm, for example about 200 sccm. Layer growth selectivity and deposition rate may be controlled by adjusting a volumetric ratio of deposition control agent to germanium precursor. A higher ratio increases deposition rate overall and improves selectivity. The volumetric flow ratio of deposition control agent to germanium precursor ranges between about 1 and about 100 for most embodiments, such as between about 10 and about 60, for example about 30. At the upper end of the range the deposition rate is about 200 Å/min, while at the low end of the range the deposition rate is about 5 Å/min. However, at the upper end of the range, film growth on dielectric regions of the substrate is not observed, while at the lower end of the range, the deposition rate on the semiconductive regions is 1-2 times the deposition rate on the dielectric regions. It should be noted, additionally, that layer growth rate and selectivity are not correlated in most cases.

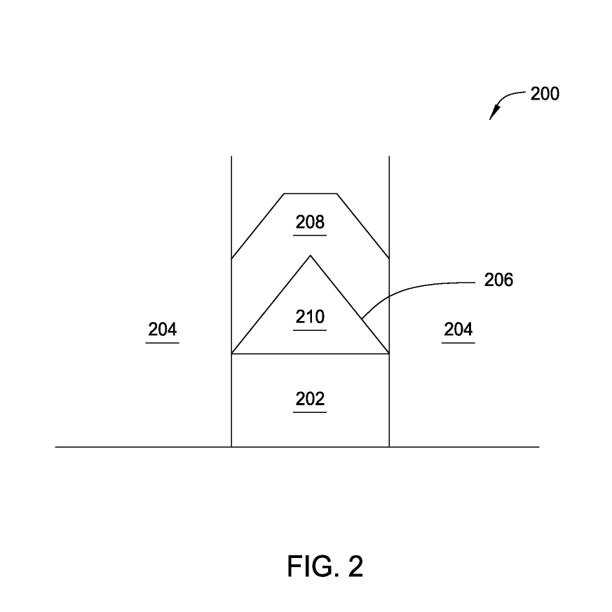

FIG. 2 is a side view of a semiconductor device structure 200 formed on a substrate 202 according to one embodiment. The substrate 202 is a semiconductor material having a first lattice constant. Dielectric isolators 204 are formed on either side of the substrate 202. A deposition surface 206 is formed on the substrate 202. A second semiconductor material 208 is formed on the deposition surface 206. The second semiconductor material 208 has a second lattice constant different from the first lattice constant. The deposition surface 206 has a lattice spacing between the first lattice constant and the second lattice constant. A ratio of the difference between the lattice spacing of the deposition surface 206 and the first lattice constant to the difference between the first lattice constant and the second lattice constant is at least 30%, such that a lattice mismatch between the deposition surface and the second semiconductor material is at least 30% less that the lattice mismatch between the first semiconductor material and the second semiconductor material.

The deposition surface 206 is a surface of a buffer layer 210 formed on the substrate 202 to reduce lattice mismatch and defect formation due to the lattice mismatch. The buffer layer 210 of FIG. 2 is faceted, such that the deposition surface 206 is a (111) surface of the buffer layer 210. The buffer layer 210 may have a composition intermediate between the first semiconductor material and the second semiconductor material. For example, the buffer layer 210 may be a blend or alloy of the first semiconductor material and the second semiconductor material. The composition of the buffer layer 210 may be varied or graded to achieve a desired lattice spacing of the deposition surface 206 without forming defects in the buffer layer 210 or the deposition surface 206. In one example, the buffer layer 206 is about 30% first semiconductor material and about 70% second semiconductor material. In another example, the buffer layer 206 has a composition that varies smoothly from about 95% first semiconductor material and about 5% second semiconductor material at the interface between the buffer layer 206 and the substrate 202 to about 5% first semiconductor material and about 95% second semiconductor material at the deposition surface 206. The buffer layer 210 can also have a composition that varies smoothly from the interface between the substrate 202 and the buffer layer 210 to the deposition surface 206, the composition of the buffer layer 210 near the interface between the buffer layer 210 and the substrate 202 being rich in the first semiconductor material, and the composition of the buffer layer 210 near the deposition surface 206 being rich in the second semiconductor material.

For preventing formation of defects in the second semiconductor material, the buffer layer 206 has a minimum thickness that depends on the degree of lattice mismatch between the first semiconductor material and the second semiconductor material. If the composition of the buffer layer is close to that of the first semiconductor material, the lattice constant of the buffer layer will be close to that of the first semiconductor material, and a relatively thin buffer layer may be used. If the buffer layer is 90% first semiconductor material and 10% second semiconductor material, the buffer layer may be less than 50 nm thick. Such a structure may result in a defect-free layer of the second semiconductor material if the lattice mismatch between the first and second semiconductor materials is less than about 3.5%. A larger lattice mismatch may need a buffer layer with a more intermediate composition, which may also be thicker to provide a defect-free layer of the second semiconductor material. In the silicon-germanium case, a buffer layer of 30% silicon and 70% germanium will support a defect-free germanium layer at a minimum thickness of about 30 nm.

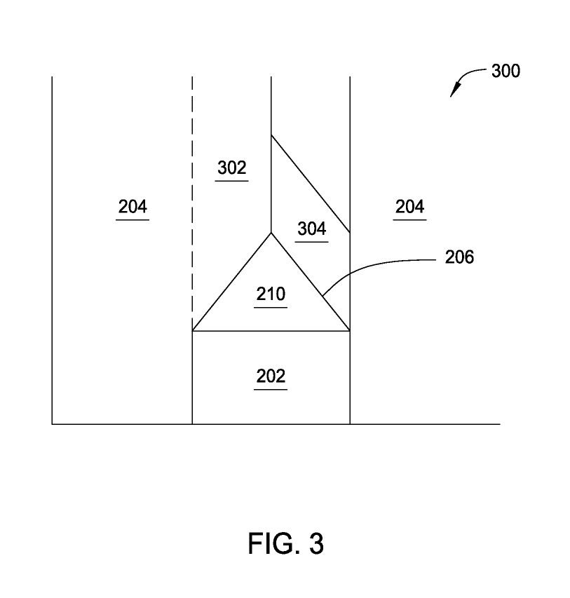

FIG. 3 is a side view of a semiconductor structure 300 formed on a substrate 202 according to another embodiment. The embodiment of FIG. 3 eliminates the ridge formation of the deposition surface 206 in FIG. 2. As in FIG. 2, the semiconductor structure 300 has a deposition surface 206 and a buffer layer 210. After forming the buffer layer 210, the trench is filled with oxide, and then a patterned resist with critical dimension of half the trench width is formed over the oxide surface. The oxide is then etched down to the deposition surface 206. The resulting trench is then filled with the second semiconductor material 304. The embodiment of FIG. 3 may result in fewer defects in the second semiconductor material 304 resulting from the ridge formation of FIG. 2.

The structure 300 of FIG. 3 may be formed by patterning a dielectric layer formed over a semiconductor substrate comprising a first semiconductor material. Patterning the dielectric layer, which may be accomplished by any dielectric patterning process suitable for a desired pattern, produces dielectric isolators at a first critical dimension and exposes the first semiconductor material in a trench. A buffer layer is then formed on the first semiconductor material in the trench. As described above, the buffer layer may be a mixture of the first semiconductor material and the second semiconductor material, and results in formation of a deposition surface, on which the second semiconductor material will be deposited.

After forming the deposition surface, the trench is filled with dielectric, which may be the same as the dielectric of the isolators, or may be a different dielectric. The dielectric filling the trench is then patterned to a second critical dimension approximately half the first critical dimension, or less. As a result, the ridge formed by the deposition surface remains covered by dielectric, and a trench is formed for depositing the second semiconductor material. At the bottom of the trench is the deposition surface, which may be angled according to the crystal structure of the buffer layer, for example a (111) surface. The deposition surface will be substantially free of defect-forming features such as ridges or cracks, however, so that filling the trench with the second semiconductor material may proceed defect-free.

In the embodiments of FIGS. 2 and 3, the first semiconductor material may be silicon and the second semiconductor material may be germanium. The buffer layer may have a silicon content between about 20 atomic percent and about 80 atomic percent. Successive buffer layers may be formed having different silicon and germanium content, migrating stepwise either from a silicon-rich buffer layer to a germanium-rich buffer layer or from a germanium-rich buffer layer to a silicon-rich buffer layer.

Similar strategies may be used to manage lattice mismatch in other layer systems. For example, if a GeSn alloy is to be formed on a Ge substrate, buffer layers having increasing amounts of Sn may be formed to avoid defect formation in the GeSn layer. For example, a first buffer layer of 6 atomic percent Sn in Ge may be formed and a second buffer layer of 12 atomic percent Sn in Ge may be formed.

While the foregoing is directed to embodiments of the invention, other and further embodiments of the invention may be devised without departing from the basic scope thereof.

What is claimed is:

1. A method of forming a semiconductor heteroepitaxial structure on a substrate, comprising:
forming a first semiconductor feature comprising a first semiconductor material and a second semiconductor material on a portion of a surface of a substrate, the portion consisting of the first semiconductor material, wherein the first semiconductor material has a first lattice constant, the second semiconductor material has a second lattice constant, and the first semiconductor feature has an exposed surface with a lattice spacing having a value between the first lattice constant and the second lattice constant; and
forming a second semiconductor feature comprising the second semiconductor material on the first semiconductor feature.

2. The method of claim 1, wherein the exposed surface is a (111) surface.

3. The method of claim 1, wherein the first semiconductor material is silicon and the second semiconductor material is germanium.

4. The method of claim 1, wherein the substrate is silicon, the first semiconductor material is a silicon-germanium material, and the second semiconductor material comprises germanium.

5. The method of claim 1, wherein the first semiconductor material is germanium and the second semiconductor material is GeSn alloy.

6. The method of claim 1, wherein the substrate has oxide isolators, and the portion of the surface of the substrate is between the oxide isolators.

7. The method of claim 1, wherein the first semiconductor feature is faceted.

8. A method of forming a semiconductor device, comprising:
forming a plurality of dielectric isolators on a semiconductor substrate to isolate a surface portion of the semiconductor substrate, the surface portion consisting of a first semiconductor material having a first lattice constant, wherein the dielectric isolators define a plurality of trenches;
forming a faceted semiconductor feature comprising the first semiconductor material and a second semiconductor material on the substrate between the dielectric isolators, the second semiconductor material having a second lattice constant different from the first lattice constant by at least 3%, wherein the faceted semiconductor feature has a lattice spacing with a value between the first lattice constant and the second lattice constant; and
forming a functional layer consisting of the second semiconductor material on the faceted semiconductor feature.

9. The method of claim 8, wherein the first semiconductor material is an elemental semiconductor.

10. The method of claim 9, wherein the second semiconductor material is an elemental semiconductor.

11. The method of claim 10, wherein the faceted semiconductor feature has an exposed (111) surface prior to forming the functional layer.

12. The method of claim 11, further comprising, between forming the faceted semiconductor feature and the functional layer, filling each trench with a dielectric material and removing a portion of the dielectric material.

13. The method of claim 12, wherein removing a portion of the dielectric material comprises etching a feature in the dielectric material with a dimension less than half that of the corresponding trench, such that the feature has substantially straight sidewalls and a sloping bottom.

14. The method of claim 13, wherein the first semiconductor material is silicon and the second semiconductor material is germanium.

15. The method of claim 14, wherein the faceted semiconductor feature is less than about 80 atomic percent germanium.

16. The method of claim 14, wherein the faceted semiconductor feature has a graded composition.

17. A method of forming a semiconductor device, comprising:
forming a plurality of silicon oxide isolators on a silicon substrate;
depositing a silicon-germanium mixture on the silicon substrate between the isolators to form a faceted feature having an exposed (111) surface, the silicon-germanium mixture having at least about 20 atomic percent silicon; and
depositing germanium on the (111) surface.

18. The method of claim 17, further comprising, between depositing the silicon-germanium mixture on the silicon substrate and depositing germanium on the (111) surface, depositing a dielectric material between the isolators and removing a portion of the dielectric material.

19. The method of claim 18, wherein removing a portion of the dielectric material comprises etching a feature in the dielectric material with a dimension less than half a thickness of the dielectric material, such that the feature has substantially straight sidewalls and a sloping bottom.
